(19) United States
(12) Patent Application Publication
(10) Pub. No.: US 2025/0255024 A1
(43) Pub. Date: Aug. 7, 2025

(54) TRAPPING FILM FOR DEEP TRENCH ISOLATION STRUCTURE

(71) Applicant: Taiwan Semiconductor Manufacturing Company, Ltd., Hsinchu (TW)

(72) Inventors: Bing Cheng You, Taichung City (TW); Feng-Chi Hung, Chu-Bei City (TW); Wen-I Hsu, Tainan City (TW); Ming-En Chen, Tainan City (TW); Jen-Cheng Liu, Hsin-Chu City (TW); Dun-Nian Yaung, Taipei City (TW)

(21) Appl. No.: 18/433,509

(22) Filed: Feb. 6, 2024

(51) Int. Cl. H01L 27/146; H01L 21/762

(52) U.S. Cl. CPC H10F 39/807; H01L 21/76232; H10F 39/811

(57) ABSTRACT

Some embodiments relate to A deep trench isolation (DTI) structure, including: a DTI core extending into a substrate; a first film surrounding the DTI core and having a first material with a first conduction band at a first band energy; a second film between the first film and the DTI core, the second film having a second material with a second conduction band at a second band energy less than the first band energy; and a third film between the second film and the DTI core, the third film having a third material with a third conduction band at a third band energy greater than the second band energy.

### BACKGROUND

In integrated circuits, front-end-of-line (FEOL) devices may interfere with one another when in close proximity. This interference may occur through the transfer of charge and parasitic capacitance that forms between the devices. Various isolation techniques have been developed to reduce the amount of dark current and parasitic capacitance that may occur between adjacent devices on a substrate. Deep trench isolation is a technique used to reduce interference between different pixels and semiconductor devices. Deep trench isolation involves the formation of deep trench isolation (DTI) structures that extend several micrometers into the substrate directly between devices on the substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, and 1C illustrate cross-sectional views and a band diagram of some embodiments of a DTI structure with a first film, a second film, and a third film surrounding a DTI core, where the second film is a trapping film.

FIGS. 2A, 2B, and 2C illustrate cross-sectional views and a top-down view of an integrated device comprising the DTI structure of FIGS. 1A and 1B.

FIGS. 3A and 3B illustrate a cross-sectional view and a band diagram of an alternative embodiment of a DTI structure comprising a fourth film extending between the DTI core and the third film.

FIGS. 4-10 illustrate a series of cross-sectional views of some embodiments of a method of forming a DTI structure with a first film, a second film, and a third film surrounding a DTI core, where the second film is a trapping film.

FIG. 11 illustrates a flowchart of some embodiments of a method of forming a DTI structure with a first film, a second film, and a third film surrounding a DTI core, where the second film is a trapping film.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A DTI structure comprises an insulative film and a DTI core. The DTI structure extends between and isolates different semiconductor devices or components on a substrate from one another, mitigating the amount of dark current and parasitic capacitance that may develop between the semiconductor devices. In some embodiments, the insulative film is silicon dioxide. The silicon dioxide insulative film has an intrinsic negative charge, which repels electrons and accumulates holes near the interface between the insulative film and the substrate. The accumulation of electron holes reduces dark current between devices separated by the DTI structure, as the dark current is dominated by electrons that are repelled by the negative charge. The DTI structure, due to the intrinsic negative charge, acts as an n-type transistor with a gate voltage below a threshold voltage. As such, the intrinsic negative charge of the insulative film creates a depletion region surrounding the DTI structure, resulting in little to no conduction between semiconductor devices separated by the DTI structure. A channel between the semiconductor devices is not induced during normal operation, as the DTI core is not biased.

As semiconductor manufacturing technology improves, semiconductor devices utilizing the new technology are frequently formed closer together to reduce the form factor, lower size limitations, and increase manufacturing yield in the device. Reducing the amount of space between the devices increases the amount of dark current the semiconductor devices may have between one another. For example, in pixel arrays, the proximity of photodetector regions, body contacts, and floating diffusion regions may result in an undesirable transfer of charge or a false reading, leading to greater interference between these components and between different pixels. The increased amount of interference between the semiconductor devices may lead to false readings of sensors and breakdown of devices in some embodiments. The amount of isolation DTI structures with a single insulative film may provide is not sufficient to effectively isolate the semiconductor devices. Therefore, a DTI structure with an increased resistance to dark current is desirable.

The present disclosure provides for a DTI structure comprising a first film, a second film, and a third film surrounding a DTI core, where the second film is a trapping film. The trapping film comprises a material that has a conduction band with a band energy significantly below (e.g., at least 1 eV below) the band energies of materials used in the first film and the third film. The difference in band energies of the materials used in the first film, the second film, and the third film creates a potential well surrounding the DTI core. A treatment is performed after the formation of the first, second and third films to capture electrons within the potential well. The captured electrons repel electrons outside of the DTI structure from the interface between the first film and the substrate. The repelling of the electrons results in an enhanced depletion region surrounding the DTI structure, accumulating a greater number of holes at the interface. The enhanced depletion region reduces the number of electrons that interact with charge traps at the interface between the substrate and the DTI structure. The greater negative charge and enhanced depletion region at the interface mitigates the dark current that may travel between the semiconductor devices isolated by the DTI structure.

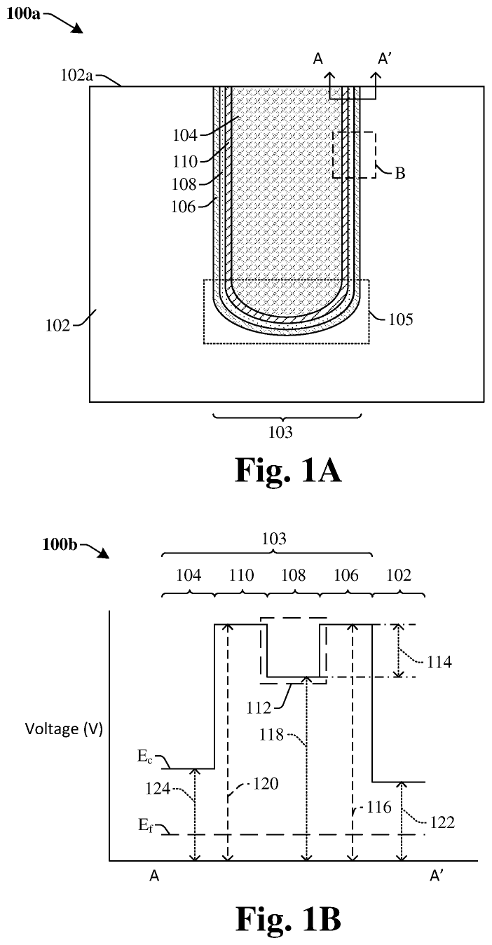

FIGS. 1A, 1B, and 1C illustrate a cross-sectional view 100a, a band diagram 100b, and a cross-sectional view 100c of some embodiments of a DTI structure with a first film, a second film, and a third film surrounding a DTI core, where the second film is a trapping film. The band diagram 100b shows the conduction band energies of layers taken along line A-A′ of FIG. 1A. The cross-sectional view 100c of FIG. 1C shows a subset of FIG. 1A taken from the rectangle B.

As shown in the cross-sectional view 100a of FIG. 1A, a DTI structure 103 extends into a substrate 102. The DTI structure 103 comprises a DTI core 104, a first film 106, a second film 108, and a third film 110. In some embodiments, the DTI core 104 is or comprises a semiconductor material, such as polysilicon or the like. The DTI core 104 is surrounded by the first film 106, the second film 108, and the third film 110. The first film 106 extends between the substrate 102 and the second film 108. The second film 108 extends between the first film 106 and the third film 110. The second film 108 may also be referred to as a trapping film. The second film 108 is spaced from the substrate 102 by the first film 106 and the second film 108 is spaced from the DTI core 104 by the third film 110. The first film 106, the second film 108, and the third film 110 space the DTI core 104 from the substrate 102. The DTI structure 103 extends from a first surface 102a of the substrate 102 and has a rounded distal end 105 facing away from the first surface 102a. The rounded distal end 105 approximately maintains a uniform thickness of the first film 106, the second film 108, and the third film 110 of the DTI structure 103, resulting in a thickness of an enhanced depletion region (see 130 of FIG. 1C) being approximately uniform around the DTI structure 103.

As shown in the band diagram 100b of FIG. 1B, a conduction band E_{c} of the DTI core 104, the first film 106, the second film 108, the third film 110, and the substrate are shown. At steady state, the layers of the DTI structure 103 have a fermi level E_{f} that is constant across the interface between the DTI structure 103 and the substrate 102. A difference between the conduction band E_{c} and the fermi level E_{f} at steady state is a property of the materials that comprise the DTI structure 103 and the substrate 102. The conduction band E_{c} measured within the first film 106 has a first band energy 116. The conduction band E_{c} measured within the second film 108 has a second band energy 118. The conduction band E_{c} measured within the third film 110 has a third band energy 120. The conduction band E_{c} measured within the substrate 102 has a fourth band energy 122. The conduction band E_{c} measured within the DTI core 103 has a fifth band energy 124. In some embodiments, the third band energy 120 is greater than the first band energy 116. In other embodiments, the third band energy 120 is equal to or less than the first band energy 116.

The first film 106 comprises a first material with the conduction band having the first band energy 116. The second film 108 comprises a second material with the conduction band having the second band energy 118. The third film 110 comprises a third material with the conduction band having the third band energy 120. In some embodiments, the first material and the second material are a same material. The first material, second material, and third material are all chosen such that the first band energy 116 and the third band energy 120 are greater than the second band energy 118 by 1 eV or more. That is, a difference 114 between the second band energy 118 and the first and third band energies 116, 120 is greater than 1 eV. This configuration results in a potential well 112 between the first film 106 and the third film 110.

The potential well 112 is configured to trap electrons in the conduction band E_{c} of the second film 108. The first film 106 and the third film 110 surrounding the second film 108 results in the isolation of the trapped electrons from a semiconductor material of the substrate 102 or the DTI core 104. In order to escape the conduction band E_{c} of the second film 108 into the substrate 102 or the DTI core 104, the electrons must be excited to the first or third band energies 116, 120 of the first film 106 or the third film 110, respectively. The difference between the second band energy 118 and the first and third band energies 116, 120 mitigates the number of electrons escaping the potential well. Further, the difference in band energies between the second film and the first and third films 106, 110 decreases the likelihood of electrons escaping the potential well without an external source of energy acting on the DTI structure 103. The trapped electrons repel electrons from the interface between the DTI structure 103 and the substrate 102, forming an enhanced depletion region at the interface. Interaction of electrons with charge traps at the interface is a dominant contributor to the dark current between isolated semiconductor devices. The enhancement of the depletion region reduces the amount of dark current that may travel around the DTI structure 103 and between semiconductor devices.

As shown in the cross-sectional view 100c of FIG. 1C, a plurality of electrons 126 are trapped in the second film 108. The plurality of electrons 126 do not escape through the first film 106 or the third film 110 due to the differences between the first, second, and third band energies (see 116, 118, and 120 of FIG. 1B). The plurality of electrons 126 repels electrons from the interface 127 between the first film 106 and the substrate 102. The repulsion of electrons forms an enhanced depletion region 130 at the interface 127 between the substrate 102 and the DTI structure 103. The enhanced depletion region 130 is dominated by electron holes 128. In some embodiments, where the first film 106 is or comprises silicon dioxide, the intrinsic negative charge of the first film 106 may further enhance the effects of the enhanced depletion region 130.

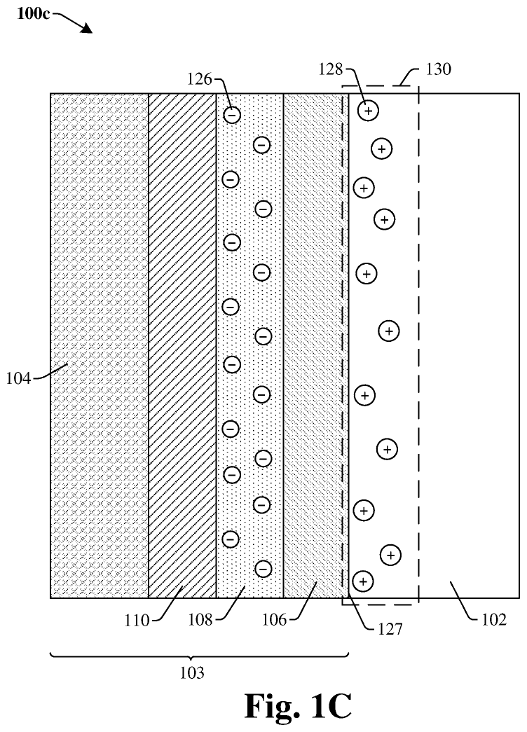

FIGS. 2A, 2B and 2C illustrate cross-sectional views 200a, 200b and a top down view 200c of an integrated device comprising the DTI structure of FIGS. 1A-1C. The cross-sectional view 200a of FIG. 2A is taken along the line A-A′ of FIG. 2C.

As shown in the cross-sectional view 200a of FIG. 2A, in some embodiments, the DTI structure 103 is a plurality of segments arranged in a grid pattern surrounding a plurality of pixels 204 arranged in an array within the substrate 102. The plurality of pixels 204 comprise photodetectors 202 that are directly between segments of the DTI structure 103. The plurality of pixels 204 further comprise floating diffusion nodes 206 and transfer transistors 208. The transfer transistors 208 are configured to activate a channel between the photodetectors 202 and the floating diffusion nodes 206, such that signals generated by the photodetectors 202 may enter an interconnect structure 210 on a first surface 102a of the substrate 102. The interconnect structure 210 comprises a plurality of contacts 212, wire levels 214, and via levels 216 arranged to guide electrical signals through the integrated device. In some embodiments, the interconnect structure 210 connected to the transfer transistor 208 and the floating diffusion nodes 206 may further connect to an image processing circuit that converts the signals from the photodetectors 202 into an image. In other embodiments, the interconnect structure 210 connected to the transfer transistor 208 and the floating diffusion nodes 206 may further couple to a security system, which results in a message being transmitted to another device in response to light shining on the photodetectors 202. In some embodiments, a plurality of color filters 218 overlie the plurality of pixels 204. In further embodiments, a plurality of lenses 220 overlie the plurality of color filters 218.

As shown in the cross-sectional view 200b of FIG. 2B, in some embodiments, the DTI structure 103 is one or more segments extending between a plurality of semiconductor devices 222. In some embodiments, the plurality of semiconductor devices 222 may comprise a transistor device (e.g., a planar FET, a FinFET, a gate-all-around (GAA) device, etc.). In some embodiments, the plurality of semiconductor devices 222 comprise source/drain terminals 224 within the substrate 102. The source/drain terminals 224 of different semiconductor devices 222 are isolated by the DTI structure 103. The semiconductor devices 222 are coupled to an interconnect structure 210. The interconnect structure 210 comprises a plurality of contacts 212, wire levels 214, and via levels 216. In embodiments without a second film (see 108 of FIG. 1A), the proximity of the source/drain terminals 224 and the biases of the source/drain terminals 224 may induce a current between the semiconductor devices 222 around the DTI structure 103. However, embodiments with the second film (see 108 of FIG. 1A) between the first and third films (see 106 and 110 of FIG. 1A) and a plurality of trapped electrons (see 126 of FIG. 1C) have an enhanced depletion region, mitigating the amount of current that may travel along the outer sidewall of the DTI structure.

As shown in the top down view 200c of FIG. 2C, in some embodiments, the DTI structure 103 is one or more segments surrounding the photodetectors 202 (shown in phantom), isolating the photodetectors 202 from one another. In some embodiments, the DTI structure 103 forms a continuous loop around one or more photodetectors 202. In some embodiments, the DTI structure does not extend to an outer surface of the substrate 102, and a capping structure (not shown) extends from an upper surface of the DTI structure 103 to the outer surface of the substrate 102. The DTI structure 103 both reduces the amount of light that may travel through the substrate 102 between the photodetectors 202, and reduces the amount of dark current that may travel between the pixels 204. The reduction in light traveling between pixels 204 increases the performance and precision of the resulting image, and the reduction in dark current reduces the number of false readings and interference between pixels 204, further improving the quality of the resulting image.

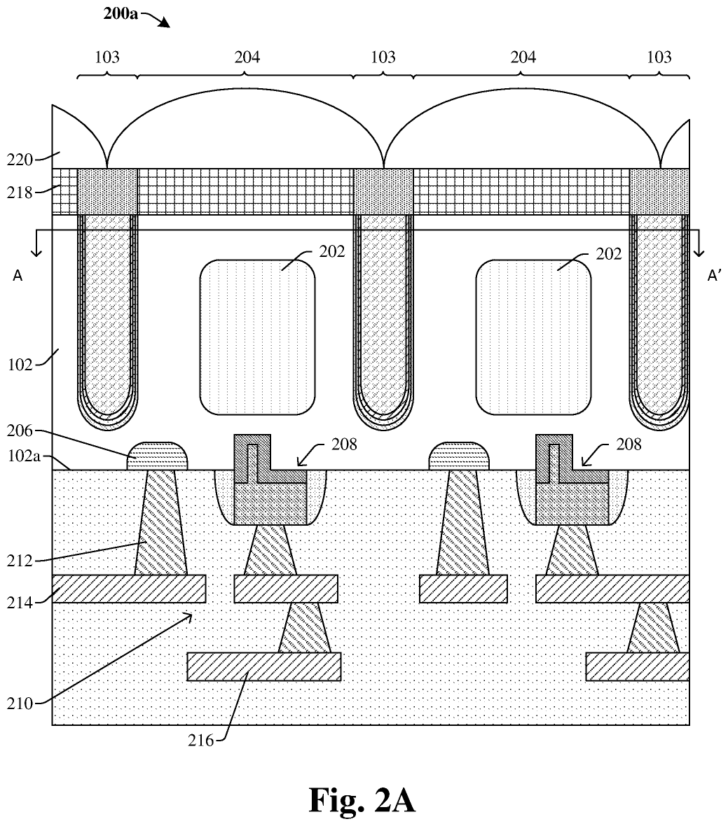

FIGS. 3A and 3B illustrate a cross-sectional view 300a and a band diagram 300b of an alternative embodiment of a DTI structure comprising a fourth film extending between the DTI core and the third film.

As shown in the cross-sectional view 300a of FIG. 3A, in some embodiments, a fourth film 302 extends between the third film 110 and the DTI core 104, separating the third film 110 from the DTI core 104. The fourth film 302 may also be referred to as an additional film. The fourth film 302 is or comprises an insulator, such as silicon dioxide or the like. In some embodiments, the fourth film 302 has a thickness equal to or greater than a thickness of the third film.

In some embodiments, the first film 106 has a first thickness between 5 and 150 angstroms, between 1 and 100 angstroms, between 2 and 120 angstroms, or within another, similar range. In some embodiments, the second film 108 has a second thickness between 5 and 150 angstroms, between 1 and 100 angstroms, between 2 and 120 angstroms, or within another, similar range. In some embodiments, the third film 110 has a third thickness between 5 and 150 angstroms, between 1 and 100 angstroms, between 2 and 120 angstroms, or within another, similar range. In some embodiments, the fourth film 302 has a fourth thickness between 5 and 300 angstroms, between 1 and 150 angstroms, between 2 and 200 angstroms, or within another, similar range. In some embodiments, the first thickness and the third thickness are substantially equal.

As shown in the band diagram 300b of FIG. 3B, the fourth film 302 has a conduction band E_{c} with a fourth band energy 304 at least 1 eV greater than the second band energy 118 of the second film 108. In some embodiments, the fourth band energy 304 is greater than the third band energy 120. In other embodiments, the fourth band energy 304 is equal to or less than the third band energy 120. In some embodiments, the fourth film 302 is configured to operate as an additional barrier between the DTI core 104 and the potential well 112 in the second film 108, further reducing the number of electrons escaping the potential well 112.

In some embodiments, the conduction band E_{c} is curved between the first film 106, the second film 108, and the third film 110 due to band bending. In further embodiments, the difference between a minimum of the second band energy 118 and a local maxima of the conduction band E_{c} within the first film 106 is greater than 1 eV. Further, the difference between the minimum of the second band energy 118 and a local maxima of the conduction band E_{c} within both the third film 110 and the fourth film 302 is greater than 1 eV.

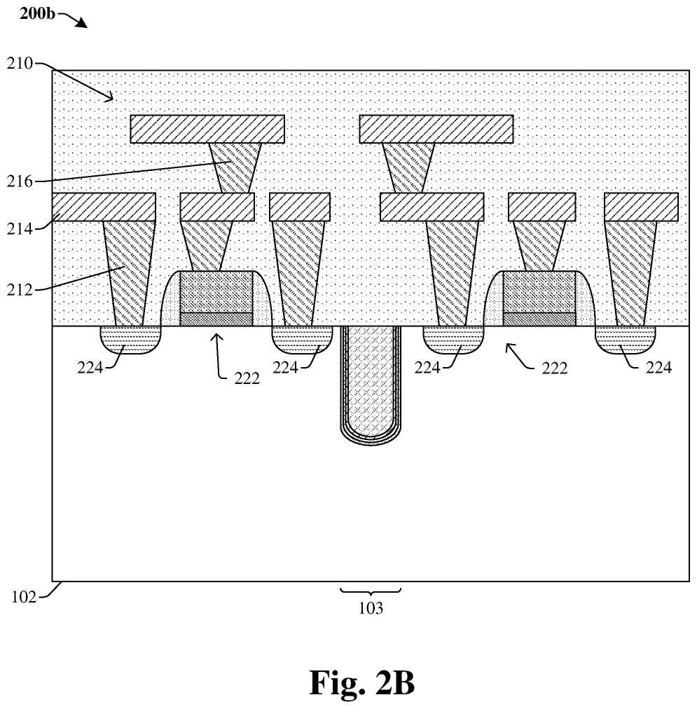

FIGS. 4-10 illustrate a series of cross-sectional views 400-1000 of some embodiments of a method of forming a DTI structure with a first film, a second film, and a third film surrounding a DTI core, where the second film is a trapping film. Although FIGS. 4-10 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

As shown in the cross-sectional view 400 of FIG. 4, a first masking layer 402 is formed over the substrate 102. The first masking layer 402 may, for example, be formed using CVD, PVD, ALD, a spin-on process, or the like. The first masking layer 402 is then patterned, revealing portions of the substrate 102 corresponding to the DTI structure (see 103 of FIG. 1A) to be formed hereafter. In some embodiments, the first masking layer 402 is or comprises a photoresist and/or the first masking layer 402 is patterned using photolithography.

After the first masking layer 402 is patterned, a first etching process 404 is performed on the substrate 102 with the first masking layer 402 in place. The first etching process 404 removes portions of the substrate exposed by the first masking layer 402, forming a first opening 406 within the substrate 102. In some embodiments, the first opening is a series of segments delineating an array on the substrate. In other embodiments, the first opening is a series of segments surrounding a portion of the substrate 102. In some embodiments, the first etching process 404 is a dry etching process. In some embodiments, the first opening 406 extends between 2 and 4 micrometers into the substrate 102, between 3 and 6 micrometers into the substrate 102, between 2 and 5 micrometers into the substrate 102, or another, similar range. In some embodiments, the substrate 102 extends another 3 to 5 micrometers beneath the first opening 406, another 4 to 6 micrometers beneath the first opening 406, another 3 to 6 micrometers beneath the first opening 406, or another, similar range. In some embodiments, the first opening 406 has a rounded bottom surface. The rounded bottom surface results in conformal layers deposited hereafter having approximately uniform thicknesses, which maintains the thickness of the enhanced depletion region (see 130 of FIG. 1C) surrounding the DTI structure (see 103 of FIG. 1C).

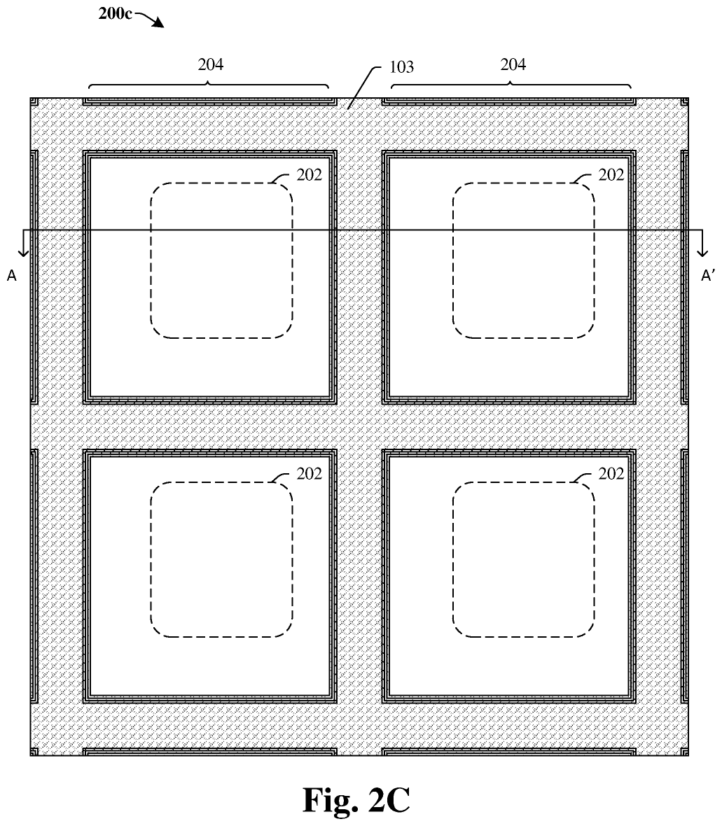

As shown in the cross-sectional view 500 of FIG. 5, the first masking layer 402 is removed. The removal of the first masking layer 402 exposes of a second side 102b of the substrate 102. In some embodiments, the first masking layer 402 is removed using one or more of a plasma etching process, a wet etching process, an ashing process, or the like.

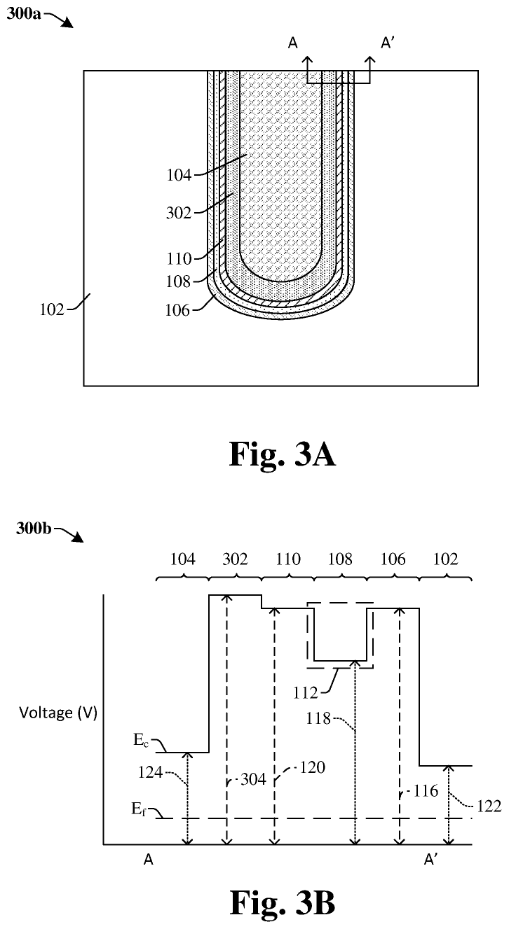

As shown in the cross-sectional view 600 of FIG. 6, a first conformal film 602 is formed over the second side 102b of the substrate 102. In some embodiments, the first conformal film 602 is or comprises a first material, such as aluminum oxide (Al₂O₃), silicon dioxide (SiO₂), or the like. In some embodiments, first conformal film 602 is formed using chemical vapor deposition (CVD), physical vapor deposition (PVD), atomic layer deposition (ALD), or the like. The first conformal film 602 overlies the second side 102b of the substrate 102 and extends along inner sidewalls and a bottom surface of the first opening 406. The first conformal film 602 conforms to the bottom surface of the first opening 406, resulting in the first conformal film 602 having a rounded cross-section within the first opening 406. In some embodiments, the thickness of the first conformal film 602 along inner sidewalls is substantially equal to the thickness of the first conformal film 602 extending along the bottom surface of the first opening 406. In some embodiments, where the first conformal film 602 comprises silicon dioxide, the first conformal film may have an intrinsic negative charge.

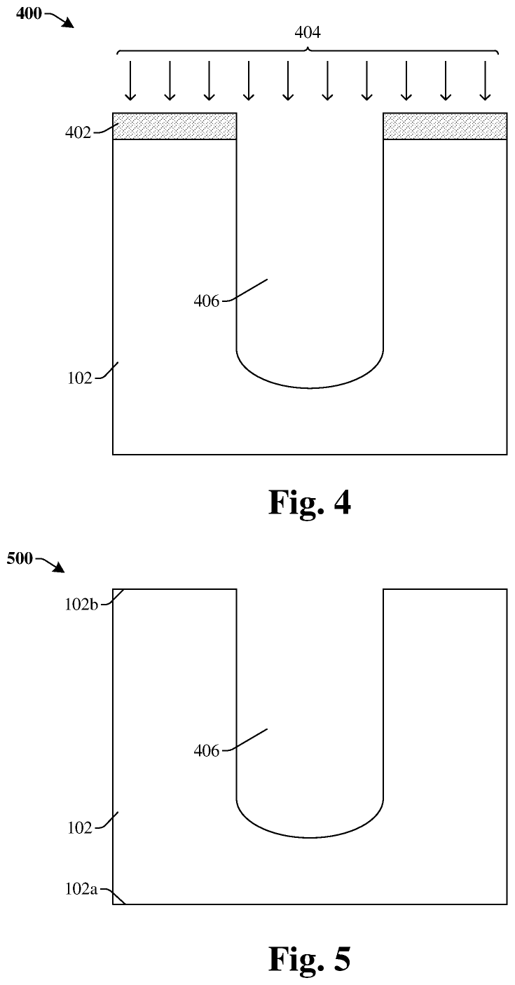

As shown in the cross-sectional view 700 of FIG. 7, a second conformal film 702 is formed over the first conformal film 602. In some embodiments, the second conformal film 702 is or comprises a second material, such as hafnium oxide (HfO₂), zirconium oxide (ZrO₂), silicon nitride (Si₃N₄), or the like. The first material of the first conformal film 602 and the second material of the second conformal film 702 are chosen to be insulators, where the first material has a conduction band with a band energy at least 1 eV less than the band energy of the conduction band of the second material. In some embodiments, second conformal film 702 is formed using CVD, PVD, ALD, or the like. The second conformal film 702 overlies the second side 102b of the substrate 102 and extends along inner sidewalls and an upper surface of the first conformal film 602 within the first opening 406. In some embodiments, the thickness of the second conformal film 702 along inner sidewalls of the first conformal film 602 is substantially equal to the thickness of the second conformal film 702 extending between the inner sidewalls of the first conformal film 602, resulting from to the rounded end of the first opening 406.

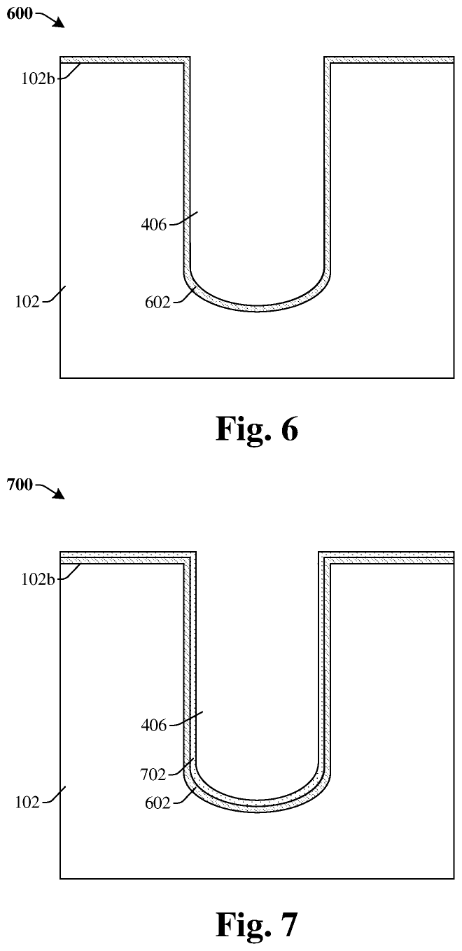

As shown in the cross-sectional view 800 of FIG. 8, a third conformal film 802 is formed over the second conformal film 702. In some embodiments, the third conformal film 802 is or comprises a third material, such as aluminum oxide (Al₂O₃), silicon dioxide (SiO₂), or the like. The third material of the third conformal film 802 is chosen to be an insulator with a conduction band having a third band energy at least 1 eV greater than the band energy of the second material. In some embodiments, the third conformal film 802 is formed using CVD, PVD, ALD, or the like. The third conformal film 802 overlies the second side 102b of the substrate 102 and extends along inner sidewalls and an upper surface of the second conformal film 702 within the first opening 406. In some embodiments, the thickness of the third conformal film 802 along inner sidewalls of the second conformal film 702 is substantially equal to the thickness of the third conformal film 802 extending between the inner sidewalls of the second conformal film 702, resulting from to the rounded end of the first opening 406 and the conformal deposition process.

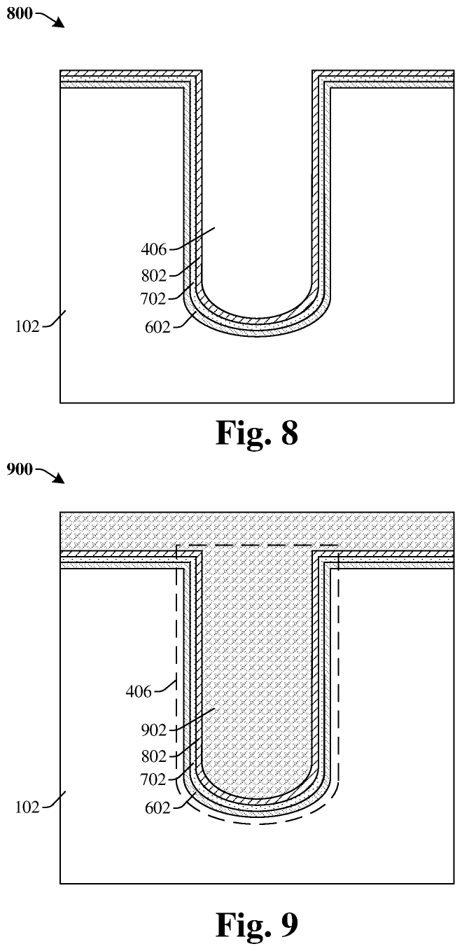

As shown in the cross-sectional view 900 of FIG. 9, a conformal fill layer 902 is formed over the third conformal film 802. In some embodiments, the conformal fill layer 902 is or comprises a semiconductor material, such as polysilicon or the like. In some embodiments, the conformal fill layer 902 is formed using CVD, PVD, ALD, or the like. The conformal fill layer 902 overlies the second side 102b of the substrate 102 and extends along inner sidewalls and an upper surface of the third conformal film 802, filling the first opening 406 (shown in phantom).

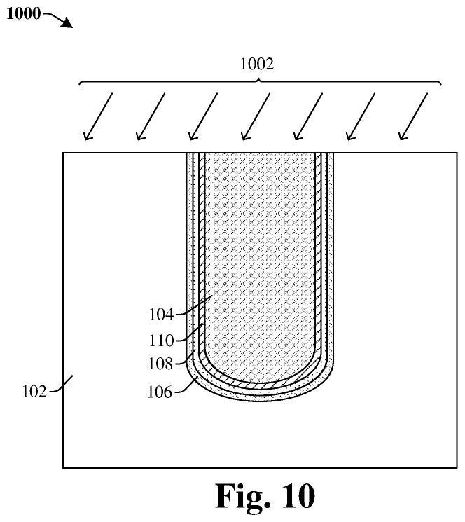

As shown in the cross-sectional view 1000 of FIG. 10, a planarization process 1002 (e.g., a chemical mechanical planarization (CMP) process) is performed. The planarization process 1002 removes portions of the first conformal film (see 602 of FIG. 9), the second conformal film (see 702 of FIG. 9), the third conformal film (see 802 of FIG. 9), and the conformal fill layer (see 902 of FIG. 9). After the planarization process 1002, the first film 106, the second film 108, the third film 110, and the DTI core 104 remain within the substrate 102.

In some embodiments, before or after the conformal fill layer (see 902 of FIG. 9) is formed and the planarization process 1002 is performed, a process treatment is performed to trap electrons within the second film 108. In some embodiments, the process treatment may be a biasing treatment, where the substrate 102 is biased such that electrons outside of the second film 108 gain enough energy to overcome the band energy of the first film 106 or the third film 110. In other embodiments, the process treatment may be a thermal treatment, where thermal energy is applied to the substrate 102 or DTI core 104 such that electrons outside of the second film 108 gain enough energy to overcome the band energy of the first film 106 or the third film 110.

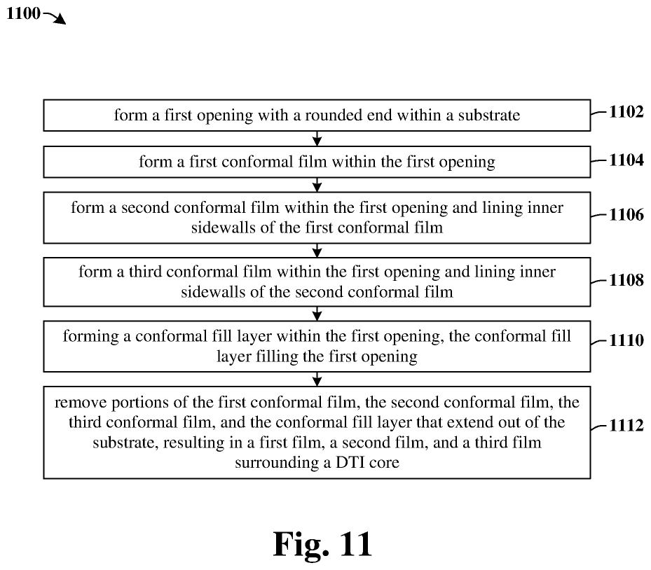

FIG. 11 illustrates a flowchart 1100 of some embodiments of a method of forming a DTI structure with a first film, a second film, and a third film surrounding a DTI core, where the second film is a trapping film. Although this method and other methods illustrated and/or described herein are illustrated as a series of acts or events, it will be appreciated that the present disclosure is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

At 1102, a first opening with a rounded end is formed within a substrate. An example of a drawing illustrating this step can be found, for example, in FIG. 4.

At 1104, a first conformal film is formed within the first opening. An example of a drawing illustrating this step can be found, for example, in FIG. 6.

At 1106, a second conformal film is formed within the first opening and lining inner sidewalls of the first conformal film. An example of a drawing illustrating this step can be found, for example, in FIG. 7.

At 1108, a third conformal film is formed within the first opening and lining inner sidewalls of the second conformal film. An example of a drawing illustrating this step can be found, for example, in FIG. 8.

At 1110, a conformal fill layer is formed within the first opening, the conformal fill layer filling the first opening. An example of a drawing illustrating this step can be found, for example, in FIG. 9.

At 1112, portions of the first conformal film, the second conformal film, the third conformal film, and the conformal fill layer that extend out of the substrate, resulting in a first film, a second film, and a third film surrounding a DTI core. An example of a drawing illustrating this step can be found, for example, in FIG. 10.

Some embodiments relate to a deep trench isolation (DTI) structure, including: a DTI core extending into a substrate; a first film surrounding the DTI core and having a first material with a first conduction band at a first band energy; a second film between the first film and the DTI core, the second film having a second material with a second conduction band at a second band energy less than the first band energy; and a third film between the second film and the DTI core, the third film having a third material with a third conduction band at a third band energy greater than the second band energy.

Other embodiments relate to an integrated device, including: a plurality of photodetectors within a substrate; a plurality of floating diffusion nodes arrayed on a first side of the substrate; an interconnect structure coupled to the plurality of floating diffusion nodes; and a deep trench isolation (DTI) core on a second side of the substrate, wherein the DTI core is spaced from the plurality of photodetectors, the plurality of floating diffusion nodes, and the interconnect structure by a first film, a second film, and a trapping film extending between the first film and the second film.

Yet other embodiments relate to a method of forming a deep trench isolation (DTI) structure, including: forming a first opening with a rounded end within a substrate; forming a first conformal film within the first opening; forming a second conformal film within the first opening and lining inner sidewalls of the first conformal film; forming a third conformal film within the first opening and lining inner sidewalls of the second conformal film; forming a conformal fill layer within the first opening, the conformal fill layer filling the first opening; and removing portions of the first conformal film, the second conformal film, the third conformal film, and the conformal fill layer that extend out of the substrate, resulting in a first film, a second film, and a third film surrounding a DTI core.

It will be appreciated that in this written description, as well as in the claims below, the terms “first”, “second”, “second”, “third” etc. are merely generic identifiers used for ease of description to distinguish between different elements of a figure or a series of figures. In and of themselves, these terms do not imply any temporal ordering or structural proximity for these elements, and are not intended to be descriptive of corresponding elements in different illustrated embodiments and/or un-illustrated embodiments. For example, “a first dielectric layer” described in connection with a first figure may not necessarily correspond to a “first dielectric layer” described in connection with another figure, and may not necessarily correspond to a “first dielectric layer” in an un-illustrated embodiment.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A deep trench isolation (DTI) structure, comprising:
a DTI core extending into a substrate;
a first film surrounding the DTI core and comprising a first material with a first conduction band at a first band energy;
a second film between the first film and the DTI core, the second film comprising a second material with a second conduction band at a second band energy less than the first band energy; and
a third film between the second film and the DTI core, the third film comprising a third material with a third conduction band at a third band energy greater than the second band energy.

2. The DTI structure of claim 1, wherein a difference between the first band energy and the second band energy is greater than 1 eV, and a difference between the second band energy and the third band energy is greater than 1 eV.

3. The DTI structure of claim 1, wherein a difference between the first band energy, the second band energy, and the third band energy results in a potential well between the first film and the second film.

4. The DTI structure of claim 3, wherein the DTI structure further comprises a rounded distal end within the substrate, and wherein the first film has a first thickness along sidewalls of the DTI structure, and a second thickness extending across the rounded distal end, and wherein the first thickness and the second thickness are substantially equal.

5. The DTI structure of claim 1, wherein the first material and the third material are a same material.

6. The DTI structure of claim 1, further comprising a fourth film between the third film and the DTI core, the fourth film comprising silicon dioxide.

7. An integrated device, comprising:
a plurality of photodetectors within a substrate;
a plurality of floating diffusion nodes arrayed on a first side of the substrate;
an interconnect structure coupled to the plurality of floating diffusion nodes; and
a deep trench isolation (DTI) core on a second side of the substrate, wherein the DTI core is spaced from the plurality of photodetectors, the plurality of floating diffusion nodes, and the interconnect structure by a first film, a second film, and a trapping film extending between the first film and the second film.

8. The integrated device of claim 7, wherein the trapping film comprises a first material and the first film and the second film respectively comprise second materials, wherein the first material has a first conduction band at a first band energy, and the second materials have second conduction bands with second band energies greater than the first band energy, and wherein a difference between the first band energy and the second band energies is greater than 1 eV.

9. The integrated device of claim 8, wherein the first material comprises silicon nitride and the second materials comprise aluminum oxide.

10. The integrated device of claim 8, further comprising an additional film between the DTI core and the first film, wherein the additional film comprising a third material having a third conduction band at a third band energy, where a difference between the first band energy and the third band energy is greater than 1 eV.

11. The integrated device of claim 7, wherein the DTI core extends in a grid pattern surrounding the plurality of photodetectors, and wherein the plurality of photodetectors are isolated from one another by the DTI core.

12. The integrated device of claim 11, wherein the first film, the trapping film, and the second film are configured to trap electrons within the trapping film.

13. The integrated device of claim 12, wherein the first film, the trapping film, and the second film are configured to mitigate an amount of dark current that travels between the plurality of photodetectors based on the trapped electrons in the trapping film.

14. A method of forming a deep trench isolation (DTI) structure, comprising:
forming a first opening with a rounded end within a substrate;
forming a first conformal film within the first opening;
forming a second conformal film within the first opening and lining inner sidewalls of the first conformal film;
forming a third conformal film within the first opening and lining inner sidewalls of the second conformal film;
forming a conformal fill layer within the first opening, the conformal fill layer filling the first opening; and
removing portions of the first conformal film, the second conformal film, the third conformal film, and the conformal fill layer that extend out of the substrate, leaving a first film, a second film, and a third film surrounding a DTI core.

15. The method of claim 14, further comprising:
performing a process treatment configured to draw electrons into the second film, wherein the process treatment is a thermal or biasing treatment.

16. The method of claim 14, wherein the second conformal film comprises a first material, and the first conformal film and the third conformal film comprises materials of a second set of materials, wherein the second set of materials comprises materials with conduction bands having a band energy at least 1 eV greater than a band energy of the first material.

17. The method of claim 14, wherein the conformal fill layer comprises a semiconductor material.

18. The method of claim 14, further comprising forming a fourth conformal film after forming the third conformal film, the fourth conformal film extending into the first opening and surrounding inner sidewalls of the third conformal film.

19. The method of claim 18, wherein the fourth conformal film comprises silicon dioxide.

20. The method of claim 14, wherein forming the first conformal film comprises a deposition process, and wherein the first conformal film has a rounded end that conforms with the rounded end of the first opening.
